(19) United States
(12) Patent Application Publication
(10) Pub. No.: US 2024/0175979 A1
(43) Pub. Date: May 30, 2024

(54) RADAR APPARATUS AND SIGNAL PROCESSING METHOD THEREIN

(71) Applicant: ELECTRONICS AND TELECOMMUNICATIONS RESEARCH INSTITUTE, Daejeon (KR)

(72) Inventors: Myung Sun SONG, Daejeon (KR); Hyung Ju KIM, Daejeon (KR); Sung Jin YOO, Daejeon (KR); Byung Jang JEONG, Daejeon (KR); Seung Keun PARK, Daejeon (KR); In Kui CHO, Daejeon (KR)

(21) Appl. No.: 18/504,343

(22) Filed: Nov. 8, 2023

(30) Foreign Application Priority Data
Nov. 21, 2022 (KR) 10-2022-0155995

(51) Int. Cl. G01S 7/35

(52) U.S. Cl. CPC G01S 7/358; G01S 13/343

(57) ABSTRACT

Exemplary embodiments provide a radar apparatus having a plurality of antenna elements and enabling to reduce a number of ADCs as long as being allowable according to a bandwidth of the ADC, reduce a chip area occupied by the ADC and interconnections in an integrated circuit, and prevent a synchronization problem between the ADCs by sampling receive signals of multiple channels at once. Frequencies of local oscillation signals used for downconverting receive signals are set to be different from each other by an amount of an offset frequency, so that each of band-limited receive signals obtained through respective RF paths may occupy a different position on a frequency axis of a frequency domain. Downconverted receive signals are combined into a single signal and converted into a single digital signal stream, and a signal processing of the digital signal stream in a digital domain enables to obtain target data.

### CROSS-REFERENCE TO RELATED APPLICATION

The present application claims a convention priority under 35 U.S.C. § 119(a) based on Korean Patent Application No. 10-2022-0155995 filed on Nov. 21, 2022, the entire content of which is incorporated herein in its entirety by reference.

### BACKGROUND

### 1. Technical Field

The present disclosure relates to a radar apparatus and, more particularly, to a radar apparatus using a continuous wave signal and employing multiple receive antennas. In addition, the present disclosure relates to a signal processing method in the radar apparatus.

### 2. Description of Related Art

Frequency-modulated continuous-wave (FMCW) radar detects a target by radiating a frequency-modulated continuous-wave signal. The FMCW radar is widely being used as a civilian radar to detect a presence of a target, a distance to the target, a speed of the target, a movement direction of the target, or an angle of arrival of the signal because of its simple system configuration despite of a low output power and a short detection range compared with a pulse radar.

FIG. 1 is a block diagram of a conventional FMCW MIMO radar using the FMCW signal and employing a multiple input multiple output (MIMO) antenna. The radar apparatus shown in FIG. 1 may include a transmit array antenna and a receive array antenna, each including a plurality of antenna elements. The antenna elements in the receive array antenna are coupled to respective receive RF blocks. Since in-phase (I) and quadrature-phase (Q) component paths are separated before a frequency conversion of a received signal to detect a phase of the signal, two downconverters are provided for each of the receive RF blocks. A downconverted receive signal is a beat signal having a frequency corresponding to a difference between the frequencies of a transmit signal and the receive signal. An analog-to-digital converter (ADC) is provided for each of the I-component and Q-component paths to change the downconverted receive signal into a digital signal.

As a result, ADCs as many as twice a number of the antennas or the RF paths are used to convert analog baseband signals into digital signals. In other words, each signal path is physically separated and a separate ADC is used for each signal path because the downconverted baseband signals occupy the same position as each other with respect to a frequency axis in the FMCW MIMO structure as shown in FIG. 2.

Meanwhile, in order to increase an angular resolution which is one of most important figure of merits of the radar and is an advantageous attribute of the FMCW MIMO radar, it is desirable to increase the number of the antenna elements disposed in the radar apparatus. However, the increase in the number of the antenna elements results in the number of the ADCs along with the number of the receive RF paths. Since the plurality of the transmit and receive RF units, the frequency downconverters, and the ADCs are mounted on a single integrated circuit (IC) chip in a typical FMCW MIMO radar, the increase in the number of the ADCs brings about an increase in the IC chip area and in the interconnection complexity in the IC chip, and a synchronization problem between the ADCs in proportion to the number of the ADCs.

### SUMMARY

Provided Exemplary embodiments provide a radar apparatus which has a plurality of antenna elements and enables to reduce a number of ADCs, e.g. to one, as long as being allowable according to a bandwidth of the ADC, reduce a chip area occupied by the ADC and interconnections in an integrated circuit, and prevent a synchronization problem between the ADCs by sampling receive signals of multiple channels at once.

Exemplary embodiments provide a signal processing method for detecting a target by using signals received through a plurality of antennas in the radar apparatus.

In a radar apparatus according to exemplary embodiments, frequencies of local oscillation signals used for downconverting receive signals are set to be different from each other by an amount of an offset frequency, so that each of band-limited receive signals obtained through respective RF paths may occupy a different position on a frequency axis of a frequency domain. Downconverted receive signals are combined into a single signal and converted into a single digital signal stream, and a signal processing of the digital signal stream in a digital domain enables to obtain target data.

The offset frequency may be set to be equal to a bandwidth of a beat signal of the radar apparatus. The bandwidth of the beat signal may be represent a maximum bandwidth of the beat signal expected in the radar apparatus. Alternatively, the offset frequency may be set to be greater than the bandwidth of the beat signal.

According to an aspect of exemplary embodiment, a radar apparatus includes: a transmit circuit configured to generate a RF transmit signal based on a local oscillation signal and comprising a transmit antenna radiating a transmit electromagnetic signal corresponding to the RF transmit signal; a receive circuit configured to detect, through a plurality of antennas, receive electromagnetic signals that the transmit electromagnetic signal was reflected by a target and propagated toward the radar apparatus and amplify detected signals to acquire n-tuple RF receive signals (where n is a natural number greater than or equal to 2); a frequency downconverter configured to convert each of the RF receive signals into an in-phase (I)-channel IF signal and a quadrature (Q)-channel IF signal such that frequency bands of 2n IF signals for the RF receive signals are sequentially displaced by a predetermined offset frequency; an analog-to-digital converter configured to perform an analog-to-digital conversion of a single IF signal into which the 2n IF signals are combined to generate a single digital signal stream; and a digital signal processor configured to processes the digital signal stream to extract target information.

The frequency downconverter may be configured to convert a frequency band of each RF receive signal into a first IF band to generate the I-channel IF signal, and shift a phase of the RF receive signal by 90 degrees and convert a frequency band of a phase-shifted RF receive signal into a second IF band different from the first IF band to generate the Q-channel IF signal.

The frequency downconverter may be configured to convert the RF receive signals into the 2n IF signals such that 2n IF bands of the 2n IF signals are sequentially displaced in a frequency domain by a predetermined offset frequency.

The offset frequency may be set to be equal to a signal bandwidth of a beat frequency of the radar apparatus.

The offset frequency may be set to be greater than a signal bandwidth of a beat frequency of the radar apparatus.

The receive circuit may include the plurality of antennas each configured to detect one of the electromagnetic signals and convert a detected electromagnetic signal into an electrical signal to output one of the RF receive signals and a plurality of low noise amplifiers each configured to amplify a corresponding one of the RF receive signals.

The frequency downconverter may include: a multiple-frequency local oscillation signal generator configured to generate (2n−1) adjusted oscillation signals having frequencies sequentially added with the offset frequency from a base frequency of the local oscillation signal and output 2n oscillation signals including the local oscillation signal and the adjusted oscillation signals, wherein the 2n oscillation signals comprises n-tuple oscillation signal pairs of two oscillation signals being out of phase by 90 degrees from each other; and a frequency conversion circuit configured to mix each of the RF receive signals with two oscillation signals of a corresponding oscillation signal pair among the 2n oscillation signals to generate the 2n IF signals.

The frequency downconverter may include: a first frequency converter configured to mix cach of the RF receive signals with the local oscillation signal and a phase-shifted local oscillation signal whose phase is shifted by 90 degrees from the local oscillation signal to generate 2n common IF band signals; a multiple-frequency local oscillation signal generator configured to generate (2n−1) offset oscillation signals having frequencies sequentially added with the offset frequency from the offset frequency; and a second frequency converter configured to mix each of a second and subsequent common IF band signals among the 2n common IF band signals with the (2n−1) offset oscillation signals, respectively, to generate the 2n IF signals including a first common IF band signal.

According to an aspect of exemplary embodiment, a signal processing method in a radar apparatus includes: detecting, by a plurality of antennas, electromagnetic signals that a transmit electromagnetic signal was reflected by a target and propagated toward the radar apparatus and amplifying detected signals to acquire n-tuple RF receive signals (where n is a natural number greater than or equal to 2); converting each of the RF receive signals into an in-phase (I)-channel IF signal and a quadrature (Q)-channel IF signal such that frequency bands of 2n IF signals for the RF receive signals are different from each other; combining the 2n IF signals to obtain a single IF signal and performing an analog-to-digital conversion of the single IF signal to generate a single digital signal stream; and processing the digital signal stream to extract target information.

The operation of converting each of the RF receive signals into the I-channel IF signal and the Q-channel IF signal may include: converting a frequency band of each RF receive signal into a first IF band to generate the I-channel IF signal; and shifting a phase of the RF receive signal by 90 degrees and converting a frequency band of a phase-shifted RF receive signal into a second IF band different from the first IF band to generate the Q-channel IF signal.

The RF receive signals may be converted into the 2n IF signals such that 2n IF bands of the 2n IF signals are sequentially displaced in a frequency domain by a predetermined offset frequency.

The offset frequency may be set to be equal to a signal bandwidth of a beat frequency of the radar apparatus.

The offset frequency may be set to be greater than a signal bandwidth of a beat frequency of the radar apparatus.

The operation of converting each of the RF receive signals into the I-channel IF signal and the Q-channel IF signal may include: generating 2n oscillation signals including the local oscillation signal used for generating the transmit electromagnetic signal and (2n−1) adjusted oscillation signals having frequencies sequentially added with the offset frequency from a base frequency of the local oscillation signal, wherein the 2n oscillation signals comprises n-tuple oscillation signal pairs of two oscillation signals being out of phase by 90 degrees from each other; and mixing each of the RF receive signals with two oscillation signals of a corresponding oscillation signal pair among the 2n oscillation signals to generate the 2n IF signals.

The operation of converting each of the RF receive signals into the I-channel IF signal and the Q-channel IF signal may include: mixing each of the RF receive signals with the local oscillation signal used for generating the transmit electromagnetic signal and a phase-shifted local oscillation signal whose phase is shifted by 90 degrees from the local oscillation signal to generate 2n common IF band signals; converting the 2n common IF band signals into the 2n IF signals in respective IF bands sequentially displaced by the offset frequency. The operation of converting the 2n common IF band signals into the 2n IF signals may include: generating (2n−1) offset oscillation signals having frequencies sequentially added with the offset frequency from the offset frequency; and mixing each of a second and subsequent common IF band signals among the 2n common IF band signals with the (2n−1) offset oscillation signals, respectively, to generate the 2n IF signals including a first common IF band signal.

According to an exemplary embodiment, the frequency of each local oscillation signal being used for the downconversion of each band-limited receive signal is set differently for each receive signal. The downconverted receive signals are combined into a single signal to be converted digitally using a single or a few ADCs, and each signal may be separated through a signal processing in a digital domain to provide digitally converted receive signal data.

The exemplary embodiment enables to reduce the number of the ADCs, e.g. to one, as long as being allowable according to the bandwidth of the ADC. Thus, the exemplary embodiment allows to reduce the chip area occupied by the ADC and the interconnections in the IC and prevent the synchronization problem between the ADCs by sampling the receive signals of multiple channels at once.

### BRIEF DESCRIPTION OF THE DRAWINGS

In order that the disclosure may be well understood, there will now be described various forms thereof, given by way of example, reference being made to the accompanying drawings, in which:

FIG. 1 is a block diagram of a conventional frequency-modulated continuous-wave (FMCW) multiple input multiple output (MIMO) radar apparatus using an FMCW signal;

FIG. 2 illustrates a baseband bandwidth and a power spectral density of each receive channel in the FMCW MIMO radar apparatus of FIG. 1;

FIG. 3 is a block diagram of a radar apparatus according to an exemplary embodiment;

FIG. 4 illustrates an example of a waveform of an RF transmit signal;

FIG. 5 is a detailed block diagram of a frequency downconverter shown in FIG. 4;

FIG. 6 is a detailed block diagram of a multiple-frequency local oscillation signal generator shown in FIGS. 3 and 5;

FIG. 7 is an illustration of a frequency spectrum of signals downconverted to an IF band;

FIG. 8 is an illustration of a frequency relationship between transmit and receive signals in the FMCW MIMO radar apparatus;

FIG. 9 is a block diagram of a radar apparatus according to another exemplary embodiment;

FIG. 10 is a detailed block diagram of a frequency downconverter shown in FIG. 9; and

FIG. 11 is a detailed block diagram of a multiple-frequency local oscillation signal generator shown in FIGS. 9 and 10.

The drawings described herein are for illustration purposes only and are not intended to limit the scope of the present disclosure in any way.

### DETAILED DESCRIPTION

For a clearer understanding of the features and advantages of the present disclosure, exemplary embodiments of the present disclosure will be described in detail with reference to the accompanied drawings. However, it should be understood that the present disclosure is not limited to particular embodiments disclosed herein but includes all modifications, equivalents, and alternatives falling within the spirit and scope of the present disclosure. In the drawings, similar or corresponding components may be designated by the same or similar reference numerals.

The terminologies including ordinals such as “first” and “second” designated for explaining various components in this specification are used to discriminate a component from the other ones but are not intended to be limiting to a specific component. For example, a second component may be referred to as a first component and, similarly, a first component may also be referred to as a second component without departing from the scope of the present disclosure. As used herein, the term “and/or” may include a presence of one or more of the associated listed items and any and all combinations of the listed items.

In the description of exemplary embodiments of the present disclosure, “at least one of A and B” may mean “at least one of A or B” or “at least one of combinations of one or more of A and B”. In addition, in the description of exemplary embodiments of the present disclosure, “one or more of A and B” may mean “one or more of A or B” or “one or more of combinations of one or more of A and B”.

When a component is referred to as being “connected” or “coupled” to another component, the component may be directly connected or coupled logically or physically to the other component or indirectly through an object therebetween. Contrarily, when a component is referred to as being “directly connected” or “directly coupled” to another component, it is to be understood that there is no intervening object between the components. Other words used to describe the relationship between elements should be interpreted in a similar fashion.

The terminologies are used herein for the purpose of describing particular exemplary embodiments only and are not intended to limit the present disclosure. The singular forms include plural referents as well unless the context clearly dictates otherwise. Also, the expressions “comprises.” “includes,” “constructed,” “configured” are used to refer a presence of a combination of stated features, numbers, processing steps, operations, elements, or components, but are not intended to preclude a presence or addition of another feature, number, processing step, operation, element, or component.

Unless defined otherwise, all terms used herein, including technical or scientific terms, have the same meaning as commonly understood by those of ordinary skill in the art to which the present disclosure pertains. Terms such as those defined in a commonly used dictionary should be interpreted as having meanings consistent with their meanings in the context of related literatures and will not be interpreted as having ideal or excessively formal meanings unless explicitly defined in the present application.

Exemplary embodiments of the present disclosure will now be described in detail with reference to the accompanying drawings. In order to facilitate general understanding in describing the present disclosure, the same components in the drawings are denoted with the same reference signs, and repeated description thereof will be omitted.

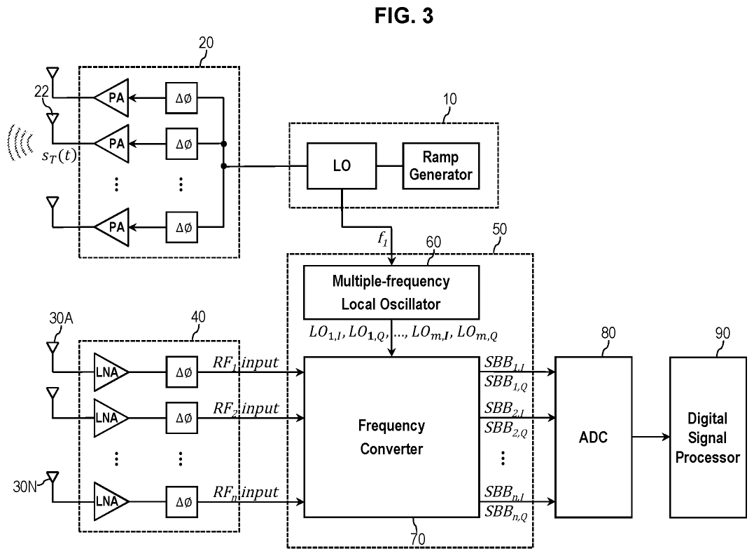

FIG. 3 is a block diagram of a radar apparatus according to an exemplary embodiment. The radar apparatus may be a frequency-modulated continuous-wave (FMCW) multiple input multiple output (MIMO) radar apparatus using a MIMO antenna to acquire reflected signals having propagated through multiple paths, and may include a chirp signal generator 10, a transmit RF circuit 20, transmit array antennas 22, receive array antennas 30A-30N, a receive RF circuit 40, a frequency downconverter 50, an analog-to-digital converter (ADC) 80, a digital signal processor 90.

The chirp signal generator 10 may include a ramp signal generator 12 generating a ramp signal and a local oscillator 14 generating a local oscillation (LO) signal based on the ramp signal to output as a chirp signal. The transmit RF circuit 20 may include a plurality of phase shifters and a plurality of power amplifiers provided correspondingly to the phase shifters. The phase shifters correct phase differences among transmission paths so that transmit signals are radiated from the transmit array antennas with the same phase. The power amplifiers amplify phase-corrected signals to generate amplified RF transmit signals S_{T}(t). The transmit array antennas 22 radiate the amplified RF transmit signals as transmit radio signals.

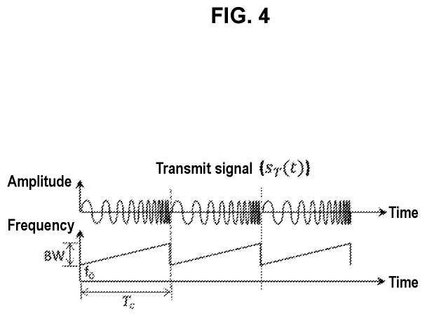

Accordingly, the chirp signal generator 10, the transmit RF circuit 20, and the transmit antennas 22 constitute a transmission circuit that generates the chirp signal, generates the RF transmit signals based on the chirp signal, and radiates the transmit radio signals corresponding to the RF transmit signals. The ramp signal generated by the ramp signal generator 12 has a waveform that its amplitude increases over time at regular intervals. The local oscillation signal or the chirp signal has a frequency determined by the amplitude of the ramp signal. Therefore, the frequency of the local oscillation signal or the chirp signal gradually increases at regular intervals. Accordingly, the RF transmit signal S_{T}(t) has a waveform that the frequency gradually increases over time at regular intervals similar to the local oscillation signal or the chirp signal as shown in FIG. 4.

Each of the receive array antennas 30A-30N has a certain operating frequency band and a receiving beam pattern and detects radio signals in the operating frequency band to convert into an electrical signal. The radio signals received by the receive array antennas 30A-30N include reflected signals that the transmit radio signal was reflected from a target and/or one or more another reflectors and propagated to the array antennas as well as noises. In the following description and claims, the signals detected by the receive array antennas 30A-30N after the reflection of the transmit radio signal from the target are referred to as “receive radio signals”, and the signals converted into the electrical signals by the receive array antennas 30A-30N are referred to as “receive signals” S_{R1}(t)-S_{Rn}(t). Each of the receive signals S_{R1}(t)-S_{Rn}(t) may be modeled as a signal whose amplitude is attenuated and delayed in time, from the RF transmit signal S_{T}(t), in proportion to a distance to the target, c.g., S_{R1}(t)=AₖS_{T}(t−τₖ). The number of the receive array antennas 30A-30N may be the same or different from the number of the transmit array antennas 22. The receive RF circuit 40 may include a first through N-th low noise amplifiers provided correspondingly to the receive array antennas 30A-30N. The low noise amplifiers amplify the receive signals S_{R1}(t)-S_{Rn}(t) detected by the receive array antennas 30A-30N to output RF receive signals RF_{1,input}-RF_{n,input}.

The frequency downconverter 50 converts frequency bands of the RF receive signals RF_{1,input}-RF_{n,input} into respective intermediate frequency (IF) bands which are different from each other. In particular, the frequency downconverter 50 converts each of the RF receive signals RF_{1,input}-RF_{n,input} into two IF bands by converting the RF receive signal into an in-phase (I)-channel IF band as well as shifting the phase of the RF receive signal by 90 degrees and converting the phase-shifted RF receive signal into a quadrature-phase (Q)-channel IF band which is different from the I-channel IF band. As each of the RF receive signals RF_{1,input}-RF_{n,input} are converted into two IF bands and n-tuple RF receive signals RF_{1.input}-RF_{n,input} are converted into respective IF bands different from each other, the frequency downconverter 50 converts the n-tuple RF receive signals RF_{1,input}-RF_{n,input} into 2n IF bands different from each other and outputs 2n IF signals. Here, the 2n IF bands are sequentially displaced in a frequency domain by a certain offset frequency Δf.

In an exemplary embodiment, the frequency downconverter 50 may include a multiple-frequency local oscillation (LO) signal generator 60 and a frequency converter 70. The multiple-frequency LO signal generator 60 receives a base LO signal from the chirp signal generator 10 and outputs the base LO signal as a first LO signal LO_{1,I}. Further, the multiple-frequency LO signal generator 60 generates (2n−1) adjusted LO signals LO_{1,Q}-LO_{n,Q} having frequencies sequentially added with the offset frequency Δf from a base frequency f₁ of the base LO signal. For each LO signal pair consisting of two consecutive LO signals among 2n LO signals LO_{1,I}-LO_{n,Q}, phases of the LO signals are set such that the phase of the LO signal LO_{j,I} (where 1≤j≤n) at an even-numbered sequence is out of phase by 90 degrees from the phase of the LO signal LO_{j,Q} at an odd-numbered sequence. The multiple-frequency LO signal generator 60 may output the 2n LO signals LO_{1,I}-LO_{n,Q} including the base LO signal LO_{1,I} and the adjusted LO signals LO_{1,Q}-LO_{n,Q} to the frequency converter 70. The frequency converter 70 may generate the 2n IF signals S_{BB}_{_{1,I}}-S_{BB}_{_{n,Q}} by mixing two consecutive LO signals LO_{j,I} and LO_{j,Q} to respective RF receive signals RF_{j,input}.

According to an exemplary embodiment, the 2n IF signals of different frequency bands may be combined into a single signal at an input terminal, for example, of the ADC 80. That is, the ADC 80 may generate a single digital signal stream by performing an analog-to-digital conversion with respect to a single IF signal resulted from combining the 2n IF signals. According to an exemplary embodiment, the ADC 80 dealing with the single IF signal may be implemented by a single ADC circuit. Therefore, in case where at least some of the radar apparatus of FIG. 3 is implemented by a semiconductor integrated circuit, the chip area occupied by the ADC and the interconnections may be reduced and the synchronization problem caused by multiple ADCs may be obviated. Meanwhile, the digital signal processor 90 may process the digital signal stream to extract target information. Operations performed by the digital signal processor 90 to extract the target information may include filtering, decimation, and other operations.

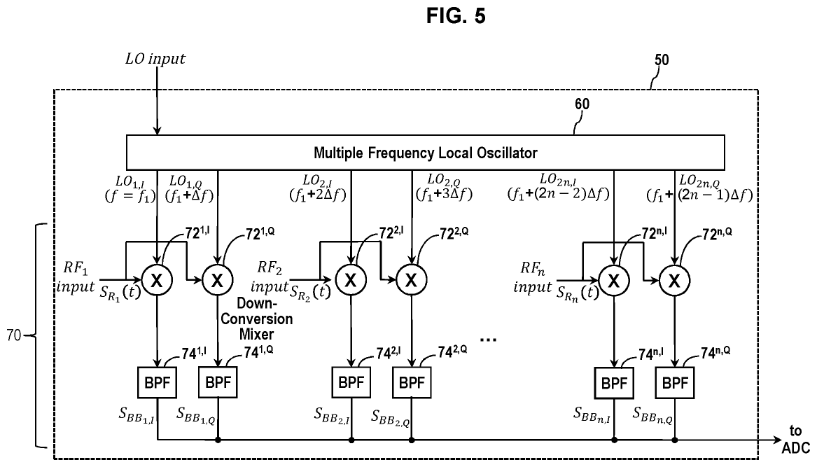

FIG. 5 is a detailed block diagram of the frequency downconverter 50 shown in FIG. 4. As mentioned above, the frequency downconverter 50 may include the multiple-frequency LO signal generator 60 and the frequency converter 70.

The multiple-frequency LO signal generator 60 generates the 2n LO signals including the first LO signal LO_{1,I}. having the same frequency as the frequency f₁ of the base LO signal input from the chirp signal generator 10 and the (2n−1) LO signals LO_{1,Q}-LO_{n,Q} having the frequencies sequentially added with the offset frequency Δf from the frequency f₁. That is, the frequency of the second LO signal LO_{1,Q} is f₁+Δf, the frequency of the third LO signal LO_{2,I} is f₁+2Δf, and the frequency of the fourth LO signal LO_{2,Q} is f₁+3Δf. In this way, the frequency of the (2n−1)-th LO signal LO_{n,I} is f₁+(2n−2)Δf, and the frequency of the 2n-th LO signal LO_{n,Q} is f₁+(2n−1)Δf.

For each LO signal pair consisting of two consecutive LO signals among 2n LO signals LO_{1,I}-LO_{n,Q}, the LO signals are out of phase by 90 degrees from each other. That is, in a first LO signal pair consisting of the LO signals LO_{1,I} and LO_{1,Q}, the phases of the LO signals LO_{1,I} and LO_{1,Q} are different from each other by 90 degrees. Also, in a second LO signal pair consisting of the LO signals LO_{2,I} and LO_{2,Q}. the phases of the LO signals LO_{2,I} and LO_{2,Q} are different from each other by 90 degrees. Similarly, in an n-th LO signal pair consisting of the LO signals LO_{n,I} and LO_{n,Q}, the phases of the LO signals LO_{n,I} and LO_{n,Q} are different from each other by 90 degrees.

The frequency converter 70 may include 2n mixers 72^{1,I}-72^{n,Q} and 2n bandpass filters 74^{1.I}-74^{n,Q}. Each of the mixers 72^{1,I}-72^{n,Q} mixes a corresponding one of the RF receive signals RF_{1,input}-RF_{n,input} with corresponding ones of the LO signals LO_{1,I}-LO_{n,Q} to convert the frequency band of the corresponding RF receive signal into the IF band. For example, the mixers 72^{1,I} and 72^{1,Q} of a first mixer pair mixes a first RF receive signal RF_{1,input} with the LO signals LO_{1,I} and LO_{1,Q} of the first LO signal pair to output an I-channel signal S_{BB}_{_{1,I}} and a Q-channel IF signal S_{BB}_{_{1,Q}} for the first RF receive signal RF_{1,input}, respectively. The mixers 72^{2,I} and 72^{2,Q} of a second mixer pair mixes a second RF receive signal RF_{2,input} with the LO signals LO_{2,I} and LO_{2,Q} of the second LO signal pair to output an I-channel IF signal S_{BB}_{_{2,I}} and a Q-channel IF signal S_{BB}_{_{2,Q}} for the second RF receive signal RF_{2,input}, respectively. Similarly, the mixers 72^{n,I} and 72^{n,Q} of an n-th mixer pair mixes an n-th RF receive signal RF_{n,input} with the LO signals LO_{n,I} and LO_{n,Q} of the n-th LO signal pair to output an I-channel IF signal S_{BB}_{_{n,I}} and a Q-channel IF signal S_{BB}_{_{n,Q}} for the n-th RF receive signal RF_{n,input}, respectively. The bandpass filters 74^{1,I}-74^{n,Q} filters the IF signals S_{BB}_{_{1,Q}}-S_{BB}_{_{n,Q}} output by the mixers 72^{1,I}-72^{n,Q}, respectively, to remove unnecessary signal components.

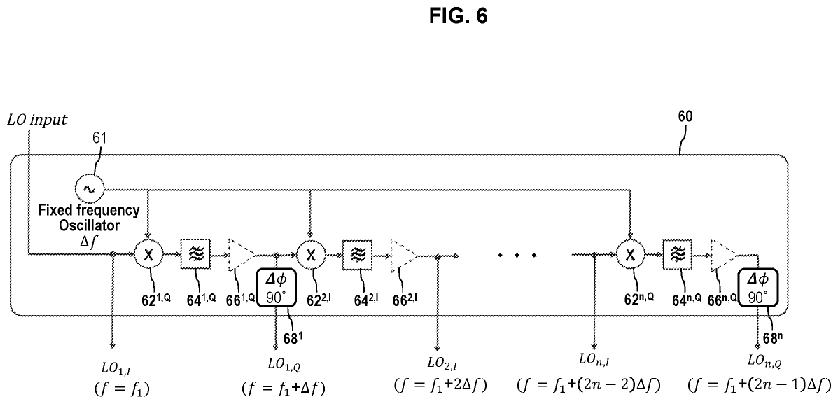

FIG. 6 is a detailed block diagram of a multiple-frequency LO generator 60 shown in FIGS. 3 and 5. In the embodiment illustrated in the drawing, the multiple-frequency LO signal generator 60 may include an oscillator 61, (2n−1) mixers 62^{1,Q}-62^{n,Q}. (2n−1) bandpass filters 64^{1,Q}-64^{n,Q}, and n phase shifters 68¹-68ⁿ. In addition, the multiple-frequency LO signal generator 60 may include (2n−1) amplifiers 66^{1,Q}-66^{n,Q} disposed at output terminals of the bandpass filters 64^{1,Q}-64^{n,Q}, respectively.

The oscillator 61 generates an offset oscillation signal having a frequency of the offset frequency Δf. The base LO signal input from the chirp signal generator 10 and having the frequency f₁ may be output as the first LO signal LO_{1,I} of the first LO signal pair. The mixer 62^{1,Q} may mix the first LO signal LO_{1,I} with the offset oscillation signal to shift the frequency band by the offset frequency Δf to the IF band centered at a frequency f₁+Δf. The bandpass filter 64^{1,Q} bandpass-filters an output signal of the mixer 62^{1,Q} to remove signal components in unnecessary frequency bands. The amplifier 66^{1,Q} may amplify an output signal of the bandpass filter 64^{1,Q} to compensate for a signal attenuation in the mixer 62^{1,Q} and/or the bandpass filter 64^{1,Q}. The phase shifter 68¹ shifts the phase of an output signal of the amplifier 66^{1,Q} by 90 degrees to output a phase-shifted signal as the second LO signal LO_{1,Q} of the first LO signal pair.

The mixer 62^{2,Q} may mix the first LO signal LO_{1,Q} with the offset oscillation signal to shift the frequency band by the offset frequency Δf to the IF band centered at a frequency f₁+2Δf. The bandpass filter 64^{2,I} bandpass-filters an output signal of the mixer 62^{2,I}, and the amplifier 66^{2,I} may amplify an output signal of the bandpass filter 64^{2,I}. An output signal of the amplifier 66^{2,I} may be output as a first LO signal LO_{2,I} of the second LO signal pair. The mixer 62^{2,Q} may mix the LO signal LO_{2,I} with the offset oscillation signal to shift the frequency band by the offset frequency Δf to the IF band centered at a frequency f₁+3Δf. The bandpass filter 64^{2,Q} bandpass-filters an output signal of the mixer 62^{2,Q}, and the amplifier 66^{2,Q} may amplify an output signal of the bandpass filter 64^{2,Q}. The phase shifter 68² shifts the phase of an output signal of the amplifier 66^{2,Q} by 90 degrees to output a phase-shifted signal as the second LO signal LO_{2,Q} of the second LO signal pair.

In this way, cach combination of a mixer, a bandpass filter, and an amplifier connected in series may generate a LO signal whose frequency is additionally increased by the offset frequency Δf from an LO signal of a previous stage. In addition, a phase shift of 90 degrees may be performed by a phase shifter for the second LO signal, i.e. the Q-channel LO signal, of each LO signal pair. As a result, the 2n LO signals LO_{1,I}-LO_{n,Q} may be generated by the multiple-frequency LO generator 60.

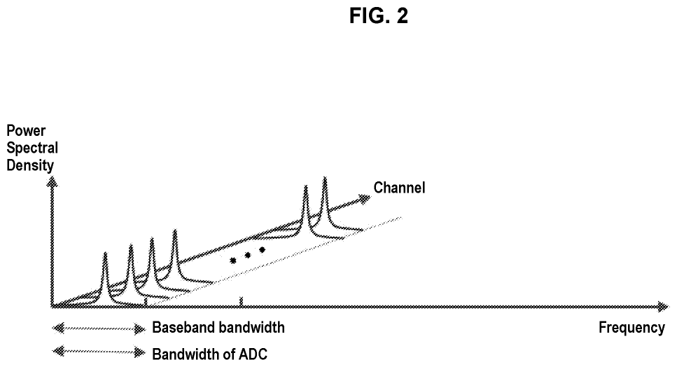

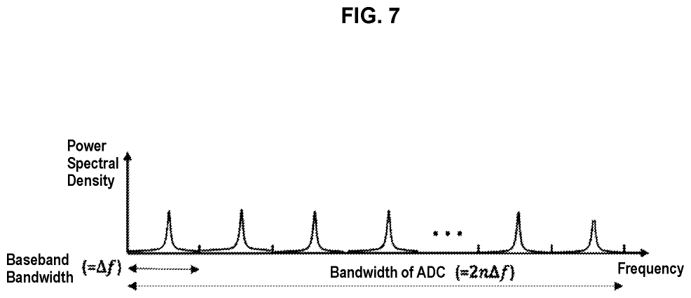

FIG. 7 illustrates a frequency spectrum of the signals downconverted to the IF band. According to the present exemplary embodiment, the frequencies of the plurality of band-limited RF receive signals RF_{1,input}-RF_{n,input} are sequentially converted to the plurality of IF bands arranged adjacently. Since the signals converted to respective IF bands do not occupy the same frequency band contrarily to the example of FIG. 2 but occupy separate positions along the frequency axis, the signals may be combined into a single IF band or baseband signal and processed properly without affecting each other. That is, the 2n IF signals in respective frequency bands may be combined into a single signal at the input terminal of the ADC 80 and converted into a single digital signal stream by a single ADC circuit.

The radar apparatus shown in FIGS. 3 through 7 operates as follows.

The chirp signal generated by the chirp signal generator 10 is phase-corrected by the transmit RF circuit 20 and radiated into free space as the transmit radio signal through the transmit array antennas 22. Though each of the transmit array antennas 22 radiates the RF transmit signal, the following description will be focused on one of the RF transmit signals S_{T}(t) radiated through one of the antennas for convenience of explanation. The radiated transmit radio signal may be detected, after being reflected by the target, as receive radio signals by the receive array antennas 30A-30N.

Each of the receive signals S_{R1}(t)-S_{Rn}(t) converted from receive radio signals into electrical signals by the receive array antennas 30A-30N are converted into a pair of IF signals including the I-channel signal and the Q-channel signal by the frequency downconverter 50. In particular, the frequency bands of the receive signals S_{R1}(t)-SRₙ(t) may be converted to respective IF bands different from each other. As a result, the frequency bands of the n-tuple RF receive signals RF_{1,input}-RF_{n,input} acquired by the receive array antennas 30A-30N are converted into 2n different IF bands. The 2n IF bands are sequentially displaced in the frequency domain by the offset frequency Δf. The 2n IF signals are combined into a single signal, converted into the digital bitstream by the ADC 80, and analyzed in the digital domain.

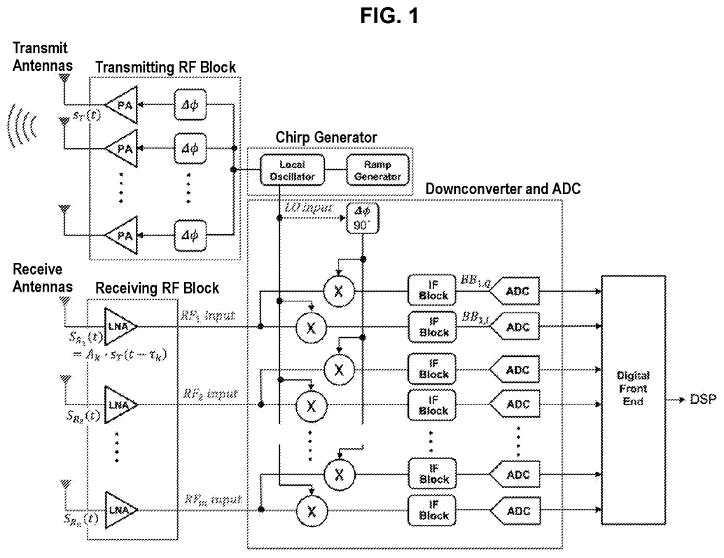

A typical FMCW radar converts the receive RF signals into baseband signals using the LO signal used for generating the transmit signal as can be seen in FIG. 1. Accordingly, IF signals or baseband signals having beat frequencies corresponding to differences in the frequencies of the transmit signal and the receive signals are input to the ADC. Generally, the FMCW radar chip is designed to be operable with the bit frequencies in a range of several tens of MHZ.

The latest ADC technologies, however, may achieve a sampling speed of several gigasamples per second (Gsps). Taking into account the difference in the actual analog-to-digital conversion speed and the feasible conversion speed, the radar apparatus according to an exemplary embodiment combines the plurality of IF signals into the single signal in which the plurality of IF signal components may be distinguished in the frequency domain, converts the combined IF signal into the digital signal by use of a single ADC having a high sampling rate, and analyzes the digital signal in the digital domain to derive target-related data.

The combined signal to be converted into the digital signal by the ADC may be regarded as a baseband signal or an IF band signal. In more detail, the combined signal may be regarded as the IF signal rather than the baseband signal in that the frequency increases periodically over time in a certain bandwidth due to the nature of the radar signal and the downconverted signal is a beat signal having a beat frequency corresponding to the frequency difference between the transmit signal and the receive signals. In particular, since the signals to be combined are sequentially displaced by the offset frequency Δf and the combined signal includes such signal components in the frequency domain according to an exemplary embodiment, the combined signal may be regarded as the IF signal considering only the position of the frequency band. Meanwhile, the combined signal may be regarded as the baseband signal because the frequency band of the signal is no longer downconverted to a lower frequency band. Therefore, in this specification, the terms “baseband signal” and “IF band signal” or “IF signal” are used interchangeably to refer to the combined signal subject to the analog-to-digital conversion.

A number of the baseband or IF band signals that may be combined and processed by the ADC may be calculated by Equation 1 assuming that the baseband signal is sampled at twice a maximum beat frequency that corresponds to the bandwidth of the baseband signal.

$$Number of baseband signals ( N ) \leq \frac{Sampling rate of ADC}{2 \times maximum beat frequency} \qquad [ Equation 1 ]$$

However, since each RF receive signal is divided into the I-channel signal and the Q-channel signal before the processing in the frequency downconverter 50, the number of RF receive signals that can be processed by one ADC may be determined by Equation 2.

$$Number of RF receive signals = \frac{Number of baseband signals}{2} \qquad [ Equation 2 ]$$

According to an exemplary embodiment, the downconverted IF signals with regard to respective RF receiving paths are combined into the single combined IF signal before the analog-to-digital conversion by the ADC as long as each of the IF signals may be discriminated from the other IF signals without interference, that is, within the range of the number of the RF receive signals allowable by a condition expressed by the Equations 1 and 2. In case where the number of the RF signal paths is too large compared with the sampling rate in the ADC, the IF signals may be grouped into two or more groups and a separate ADC may be used for each group.

The frequency downconversion process will now be described in more detail with reference to FIGS. 5 and 6.

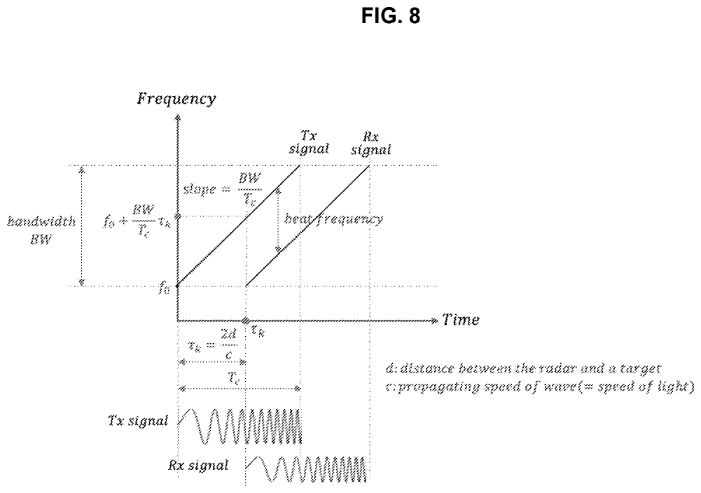

FIG. 8 illustrates a frequency relationship between the transmit signal and one of the receive signals in the FMCW MIMO radar apparatus. The frequencies of the chirp signal and the RF transmit signal periodically rise from a lower limit f₀ to an upper limit

$${f}_{0} + \frac{BW}{{T}_{c}}$$

with a slope BW/T_{c} at a certain period T_{c}. The receive signal is detected when a delay time of

$${τ}_{k} = \frac{2 d}{c}$$

has elapsed after the emission of the transmit signal, where d denotes a distance from the radar apparatus to the target and c represents a propagation speed of the electromagnetic wave in free space, i.e., the speed of light. The difference between the frequency of the transmit signal and the frequency of the receive signal at any point in time becomes the beat frequency.

The transmit signal S_{T}(t) transmitted through one of the transmit antennas may be expressed by Equation 3.

$${s}_{T} ( t ) = cos ( 2 π {f}_{0} t + 2 π \frac{1}{2} \frac{BW}{{T}_{c}} {t}^{2} + {∅}_{0} ( t ) ) \qquad [ Equation 3 ]$$

where Ø₀(t) is an initial phase.

Meanwhile, the LO signals used for the downconversion of the receive signal for each RF path have frequencies size obtained by adding the offset frequency Δf once or a plurality of times to the frequency f₁ of the base LO signal. In detail, the LO signal LO_{m,I}(t) for the I-channel of the m-th path may be expressed by Equation 4.

$${LO}_{m , I} ( t ) = cos ( 2 π ( {f}_{0} + m Δ f ) t + 2 π \frac{1}{2} \frac{BW}{{T}_{c}} {t}^{2} + {∅}_{0} ( t ) ) \qquad [ Equation 4 ]$$

The transmit signal S_{T}(t) may be reflected at a k-th target and may be detected by an m-th receive antenna among the receive array antennas 30A-30N. An m-th RF receive signal RF_{m,input} detected by the m-th receive antenna after the reflection of the transmit signal S_{T}(t) at the k-th target may be converted by using the LO signal LO_{m,1}(t). A band-converted I-channel IF signal S_{BB}_{_{I}}(t) may be expressed by Equation 5.

$$\begin{matrix}{S}_{{BB}_{I}} ( t ) = {s}_{R} ( t ) \cdot {LO}_{m , I} ( t ) \\ = {A}_{k} \cdot {s}_{T} ( t - {τ}_{k} ) \cdot {LO}_{m , I} ( t )\end{matrix} \qquad [ Equation 5 ]$$

$$\begin{matrix}{S}_{{BB}_{I}} ( t ) = {A}_{k} \cdot cos ( 2 π {f}_{0} ( t - {τ}_{k} ) + 2 π \frac{1}{2} \frac{BW}{{T}_{c}} {( t - {τ}_{k} )}^{2} + {∅}_{0} ( t - {τ}_{k} ) ) \cdot cos ( 2 π ( {f}_{0} + m Δ f ) t + 2 π \frac{1}{2} \frac{BW}{{T}_{c}} {t}^{2} + {∅}_{0} ( t ) ) \\ = \frac{1}{2} {A}_{k} \cdot \{ \begin{matrix}cos ( 2 π {f}_{0} ( t - {τ}_{k} ) + 2 π \frac{1}{2} \frac{BW}{{T}_{c}} {( t - {τ}_{k} )}^{2} + {∅}_{0} ( t - {τ}_{k} ) - 2 π ( {f}_{0} + m Δ f ) t - 2 π \frac{1}{2} \frac{BW}{{T}_{c}} {t}^{2} - {∅}_{0} ( t ) ) + \\ cos ( 2 π {f}_{0} ( t - {τ}_{k} ) + 2 π \frac{1}{2} \frac{BW}{{T}_{c}} {( t - {τ}_{k} )}^{2} + {∅}_{0} ( t - {τ}_{k} ) + 2 π ( {f}_{0} + m Δ f ) t + 2 π \frac{1}{2} \frac{BW}{{T}_{c}} {t}^{2} + {∅}_{0} ( t ) )\end{matrix} \} \\ = \frac{1}{2} {A}_{k} \cdot \{ \begin{matrix}cos ( 2 π {f}_{0} t - 2 π {f}_{0} {τ}_{k} + 2 π \frac{1}{2} \frac{BW}{{T}_{c}} ( {t}^{2} - 2 {τ}_{k} t + {τ}_{k}^{2} ) + {∅}_{0} ( t - {τ}_{k} ) - 2 π {f}_{0} t - 2 π m Δ ft - 2 π \frac{1}{2} \frac{BW}{{T}_{c}} {t}^{2} - {∅}_{0} ( t ) ) + \\ cos ( 2 π {f}_{0} t - 2 π {f}_{0} {τ}_{k} + 2 π \frac{1}{2} \frac{BW}{{T}_{c}} ( {t}^{2} - 2 {τ}_{k} t + {τ}_{k}^{2} ) + {∅}_{0} ( t - {τ}_{k} ) + 2 π {f}_{0} t + 2 π m Δ ft + 2 π \frac{1}{2} \frac{BW}{{T}_{c}} {t}^{2} + {∅}_{0} ( t ) )\end{matrix} \} \\ = \frac{1}{2} {A}_{k} \cdot \{ \begin{matrix}cos ( 2 π {f}_{0} {τ}_{k} + 2 π \frac{BW}{{T}_{c}} {τ}_{k} t - 2 π \frac{1}{2} \frac{BW}{{T}_{c}} {τ}_{k}^{2} - {∅}_{0} ( t - {τ}_{k} ) + 2 π m Δ ft + {∅}_{0} ( t ) ) + \\ cos ( 2 π \cdot ( 2 {f}_{0} ) t - 2 π {f}_{0} {τ}_{k} + 2 π \frac{BW}{{T}_{c}} {t}^{2} - 2 π \frac{1}{2} \frac{BW}{{T}_{c}} {τ}_{k}^{2} + {∅}_{0} ( t - {τ}_{k} ) + 2 π m Δ ft + {∅}_{0} ( t ) )\end{matrix} \} \\ = \frac{1}{2} {A}_{k} \cdot \{ \begin{matrix}cos ( 2 π m Δ ft + 2 π {f}_{0} {τ}_{k} + 2 π \frac{BW}{{T}_{c}} {τ}_{k} t - 2 π \frac{1}{2} \frac{BW}{{T}_{c}} {τ}_{k}^{2} + {∅}_{0} ( t ) - {∅}_{0} ( t - {τ}_{k} ) ) + \\ cos ( 2 π \cdot ( 2 {f}_{0} + 2 π m Δ f ) t - 2 π {f}_{0} {τ}_{k} + 2 π \frac{BW}{{T}_{c}} {t}^{2} - 2 π \frac{BW}{{T}_{c}} {τ}_{k} t + 2 π \frac{1}{2} \frac{BW}{{T}_{c}} {τ}_{k}^{2} + {∅}_{0} ( t ) + {∅}_{0} ( t - {τ}_{k} ) )\end{matrix} \}\end{matrix}$$

When the IF signal S_{BB}_{_{I}}(t) undergoes the bandpass filtering or lowpass filtering, the unnecessary signal components having the frequenciey of 2f₀+2πmΔf are removed and only the following baseband components remain.

$$\begin{matrix}{s}_{{BB}_{I}} ( t ) = \frac{1}{2} {A}_{k} \cdot cos ( 2 π m Δ ft + 2 π \frac{BW}{{T}_{c}} {τ}_{k} t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) ) \\ = \frac{1}{2} {A}_{k} \cdot cos ( 2 π ( m Δ f + \frac{BW}{{T}_{c}} {τ}_{k} ) t + ( 2 π {f}_{0} {τ}_{k} - 2 π \frac{1}{2} \frac{BW}{{T}_{c}} {τ}_{k}^{2} ) + {∅}_{0} ( t ) - {∅}_{0} ( t - {τ}_{k} ) )\end{matrix} \qquad [ Equation 6 ]$$

As can be seen in the above equation, when a signal with a frequency of (f₁+mΔf) is used as a local oscillation signal for the frequency conversion, the frequency band of the baseband or IF band signal is changed on the frequency axis by an amount of mΔf. Thus, if the frequency of the LO signal used for the frequency conversion for each path is different from the frequency for the previous path by Δf, the position of the frequency band occupied by each IF signal is changed so that the signals can be combined on the frequency axis without changing other parameters.

Meanwhile, the m-th RF receive signal RF_{m,input} detected by the m-th receive antenna after the reflection of the transmit signal S_{T}(t) at the k-th target may also be converted by using the LO signal LO_{m,Q}(t). The LO signal LO_{m,Q}(t) for the Q-channel of the m-th path may be expressed by Equation 7. A band-converted Q-channel IF signal S_{BB}_{_{Q}}(t) may be expressed by Equation 8.

$${LO}_{M , Q} ( t ) = sin ( 2 π ( {f}_{0} + m Δ f ) t + 2 π \frac{1}{2} \frac{BW}{{T}_{c}} {t}^{2} + {∅}_{0} ( t ) ) \qquad [ Equation 7 ]$$

$$\begin{matrix}{S}_{{BB}_{Q}} ( t ) = {s}_{R} ( t ) \cdot {LO}_{m , Q} ( t ) \\ = {A}_{k} \cdot {s}_{T} ( t - {τ}_{k} ) \cdot {LO}_{m , Q} ( t )\end{matrix} \qquad [ Equation 8 ]$$

$$\begin{matrix}{S}_{{BB}_{Q}} ( t ) = {A}_{k} \cdot cos ( 2 π {f}_{0} ( t - {τ}_{k} ) + 2 π \frac{1}{2} \frac{BW}{{T}_{c}} {( t - {τ}_{k} )}^{2} + {∅}_{0} ( t - {τ}_{k} ) ) \cdot sin ( 2 π ( {f}_{0} + m Δ f ) t + 2 π \frac{1}{2} \frac{BW}{{T}_{c}} {t}^{2} + {∅}_{0} ( t ) ) \\ = \frac{1}{2} {A}_{k} \cdot \{ \begin{matrix}sin ( 2 π {f}_{0} ( t - {τ}_{k} ) + 2 π \frac{1}{2} \frac{BW}{{T}_{c}} {( t - {τ}_{k} )}^{2} + {∅}_{0} ( t - {τ}_{k} ) + 2 π ( {f}_{0} + m Δ f ) t + 2 π \frac{1}{2} \frac{BW}{{T}_{c}} {t}^{2} + {∅}_{0} ( t ) ) - \\ sin ( 2 π {f}_{0} ( t - {τ}_{k} ) + 2 π \frac{1}{2} \frac{BW}{{T}_{c}} {( t - {τ}_{k} )}^{2} + {∅}_{0} ( t - {τ}_{k} ) - 2 π ( {f}_{0} + m Δ f ) t - 2 π \frac{1}{2} \frac{BW}{{T}_{c}} {t}^{2} - {∅}_{0} ( t ) )\end{matrix} \} \\ = \frac{1}{2} {A}_{k} \cdot \{ \begin{matrix}sin ( 2 π {f}_{0} t - 2 π {f}_{0} {τ}_{k} + 2 π \frac{1}{2} \frac{BW}{{T}_{c}} ( {t}^{2} - 2 {τ}_{k} t + {τ}_{k}^{2} ) + {∅}_{0} ( t - {τ}_{k} ) + 2 π {f}_{0} t + 2 π m Δ ft + 2 π \frac{1}{2} \frac{BW}{{T}_{c}} {t}^{2} + {∅}_{0} ( t ) ) - \\ sin ( 2 π {f}_{0} t - 2 π {f}_{0} {τ}_{k} + 2 π \frac{1}{2} \frac{BW}{{T}_{c}} ( {t}^{2} - 2 {τ}_{k} t + {τ}_{k}^{2} ) + {∅}_{0} ( t - {τ}_{k} ) - 2 π {f}_{0} t - 2 π m Δ ft - 2 π \frac{1}{2} \frac{BW}{{T}_{c}} {t}^{2} - {∅}_{0} ( t ) )\end{matrix} \} \\ = \frac{1}{2} {A}_{k} \cdot \{ \begin{matrix}sin ( 2 π ( 2 {f}_{0} ) t - 2 π {f}_{0} {τ}_{k} + 2 π \frac{BW}{{T}_{c}} {t}^{2} - 2 π \frac{BW}{{T}_{c}} {τ}_{k} t + 2 π \frac{1}{2} \frac{BW}{{T}_{c}} {τ}_{k}^{2} + {∅}_{0} ( t - {τ}_{k} ) + 2 π m Δ ft + {∅}_{0} ( t ) ) - \\ sin ( - 2 π {f}_{0} {τ}_{k} - 2 π \frac{BW}{{T}_{c}} {τ}_{k} t + 2 π \frac{1}{2} \frac{BW}{{T}_{c}} {τ}_{k}^{2} + {∅}_{0} ( t - {τ}_{k} ) - 2 π m Δ ft - {∅}_{0} ( t ) )\end{matrix} \} \\ = \frac{1}{2} {A}_{k} \cdot \{ \begin{matrix}sin ( 2 π ( 2 {f}_{0} + 2 π m Δ ft ) t - 2 π {f}_{0} {τ}_{k} + 2 π \frac{BW}{{T}_{c}} {t}^{2} - 2 π \frac{BW}{{T}_{c}} {τ}_{k} t + 2 π \frac{1}{2} \frac{BW}{{T}_{c}} {τ}_{k}^{2} + {∅}_{0} ( t ) + {∅}_{0} ( t - {τ}_{k} ) ) + \\ sin ( 2 π m Δ f ) t + 2 π {f}_{0} {τ}_{k} + 2 π \frac{BW}{{T}_{c}} {τ}_{k} t - 2 π \frac{1}{2} \frac{BW}{{T}_{c}} {τ}_{k}^{2} + {∅}_{0} ( t ) - {∅}_{0} ( t - {τ}_{k} ) )\end{matrix} \}\end{matrix}$$

When the IF signal S_{BB}_{_{Q}}(t) undergoes the bandpass filtering or lowpass filtering, the unnecessary signal components having the frequenciey of 2f₀+2πmΔf are removed and only the following baseband components remain.

$$\begin{matrix}{S}_{{BB}_{Q}} ( t ) = \frac{1}{2} {A}_{k} \cdot sin ( 2 π ( m Δ f ) t + 2 π {f}_{0} {τ}_{k} + 2 π \frac{BW}{{T}_{c}} {τ}_{k} t - 2 π \frac{1}{2} \frac{BW}{{T}_{c}} {τ}_{k}^{2} + {∅}_{0} ( t ) - {∅}_{0} ( t - {τ}_{k} ) ) \\ = \frac{1}{2} {A}_{k} \cdot sin ( 2 π ( m Δ f + \frac{BW}{{T}_{c}} {τ}_{k} ) t + ( 2 π {f}_{0} {τ}_{k} - 2 π \frac{1}{2} \frac{BW}{{T}_{c}} {τ}_{k}^{2} ) + {∅}_{0} ( t ) - {∅}_{0} ( t - {τ}_{k} ) )\end{matrix} \qquad [ Equation 9 ]$$

As can be seen in the above equation, when a signal with a frequency of (f₁+mΔf) is used as a local oscillation signal for the frequency conversion, the frequency band of the baseband or IF band signal is changed also for the Q-channel on the frequency axis by an amount of mΔf. Thus, if the frequency of the LO signal used for the frequency conversion for each channel is different from the frequency for the previous channel by Δf, the position of the frequency band occupied by each IF signal is changed so that the signals can be combined on the frequency axis without changing other parameters.

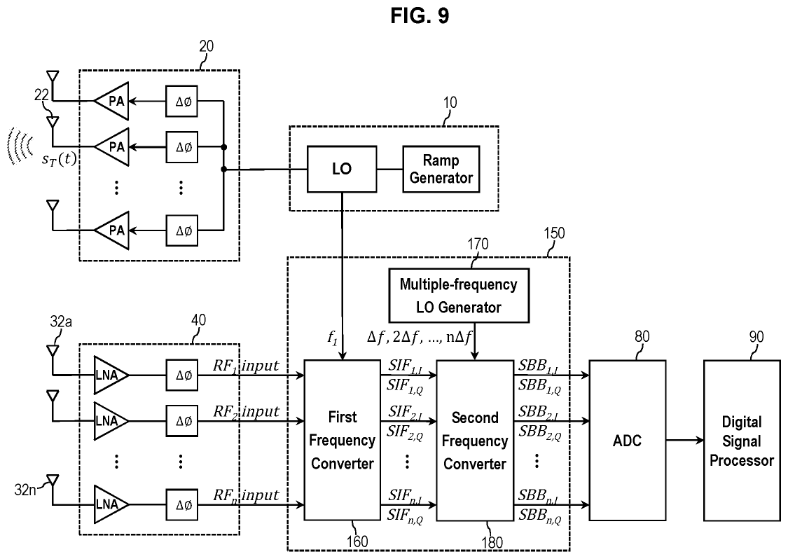

FIG. 9 is a block diagram of the radar apparatus according to another exemplary embodiment. According to this embodiment, a plurality of RF receive signals are first converted to a same IF band and then converted to respective IF bands different from each other unlike the embodiment shown in FIG. 3 where a plurality of RF receive signals are directly converted to a plurality of IF bands. The radar apparatus may include the chirp signal generator 10, the transmit RF circuit 20, the transmit array antennas 22, the receive array antennas 30A-30N, the receive RF circuit 40, a frequency downconverter 150, the ADC 80, and the digital signal processor 90. The components shown in FIG. 9 except for the frequency downconverter 150 are similar to the components shown in FIG. 3, and thus the detailed descriptions thereof will be omitted for simplicity.

The frequency downconverter 150 converts the frequency bands of the RF receive signals RF_{1,input}-RF_{n,input} into respective IF bands which are different from each other. In particular, the frequency downconverter 50 converts each of the RF receive signals RF_{1,input}-RF_{n,input} into two IF bands by converting the RF receive signal into the I-channel IF band as well as shifting the phase of the RF receive signal by 90 degrees and converting the phase-shifted RF receive signal into the Q-channel IF band which is different from the I-channel IF band. As each of the RF receive signals RF_{1,input}-RF_{n,input} are converted into two IF bands and n-tuple RF receive signals RF_{1,input}-RF_{n,input} are converted into respective IF bands different from each other, the frequency downconverter 50 converts the n-tuple RF receive signals RF_{1,input}-RF_{n,input} into 2n IF bands different from each other and outputs 2n IF signals. Here, the 2n IF bands are sequentially displaced in a frequency domain by a certain offset frequency Δf.

In the embodiment of FIG. 9, the frequency downconverter 150 may include a first frequency converter 160, a multiple-frequency LO signal generator 170, and a second frequency converter 180. The first frequency converter 160 mixes an LO signal LO_{I} and a phase-shifted LO signal LO_{Q} of which phase is shifted by 90 degrees from the LO signal LO_{I} to the n-tuple RF receive signals RF_{1,input}-RF_{n,input} to generate 2n common IF band signals S_{BB}_{_{1,I}}-S_{BB}_{_{n,Q}}. Accordingly, the 2n common IF band signals S_{BB}_{_{1,I}}-S_{BB}_{_{n,Q}} generated from the plurality of RF receive signals RF_{1,input}-RF_{n,input} are in the same IF band. The multiple-frequency LO signal generator 170 generates (2n−1) offset oscillation signals having frequencies sequentially added with the offset frequency Δf from the offset frequency Δf. The second frequency converter 180 outputs a first common IF band signal S_{IF}_{_{1,I}} among the 2n common IF band signals S_{IF}_{_{1,I}}-S_{IF}_{_{n,Q}} from the first frequency converter 160 as is, and mixes the (2n−1) offset oscillation signals to the remaining common IF band signals S_{IF}_{_{1,Q}}-S_{IF}_{_{n,Q}}, respectively, to generate (2n−1) IF signals S_{BB}_{_{1,I}}-S_{BB}_{_{n,Q}}. Accordingly, the 2n common IF band signals S_{IF}_{_{1,I}}-S_{IF}_{_{n,Q}} in the common IF band are converted into IF signals S_{BB}_{_{1,I}}-S_{BB}_{_{nnQ}} of different bands.

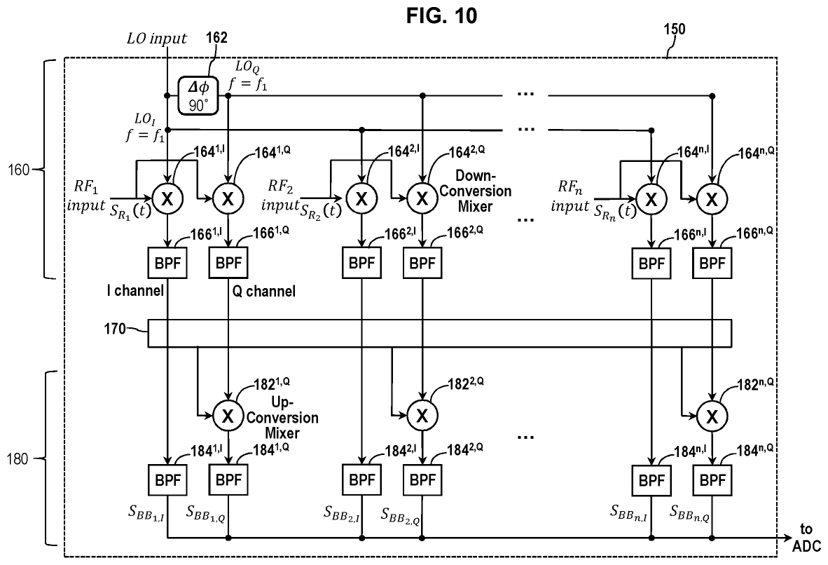

FIG. 10 is a detailed block diagram of the frequency downconverter 150 shown in FIG. 9.

The first frequency converter 160 may include a phase shifter 162, 2n mixers 162^{1,I}-164^{n,Q}, and 2n bandpass filters 166^{1,I}-166^{n,Q}. The phase shifter 162 shifts the phase of the LO signal LOI from the chirp signal generator 10 of a transmission circuit by 90 degrees to generate the phase-shifted LO signal LO_{Q}. Each of the mixers 162^{1,I}-164^{n,Q} mixes one of the RF receive signals RF_{1,input}-RF_{n,input} with either the LO signal LO_{I} or the phase-shifted LO signal LO_{Q} to generate the common IF band signals S_{IF}_{_{1,I}}-S_{IF}_{_{n,Q}}. Among the mixers 162^{1,I}-164^{n,Q}, every two mixers form a pair and the same RF receive signal, so that one mixer of the pair mixes the RF receive signal with the LO signal LO_{I} while the other mixer of the pair mixes the RF receive signal with the phase-shifted LO signal LO_{Q}. The LO signal LO_{I} and the phase-shifted LO signal LO_{Q} are alternately applied to the mixers 162^{1,I}-164^{n,Q}.

For example, the mixer 164^{1,I} mixes the RF receive signal RF_{1,input} with the LO signal LO_{I} to generate the common IF band signal SIF_{1,I}, and the mixer 164^{1,Q} mixes the RF receive signal RF_{1,input} with the phase-shifted LO signal LO_{Q} to generate the common IF band signal S_{IF}_{_{1,Q}}. The mixer 164^{2,I} mixes the RF receive signal RF_{2,input} with the LO signal LO_{I} to generate the common IF band signal S_{IF}_{_{2,I}}, and the mixer 164^{2,Q} mixes the RF receive signal RF_{2,input} with the phase-shifted LO signal LO_{Q} to generate the common IF band signal S_{IF}_{_{2,Q}}. In this way, mixer 164^{n,I} mixes the RF receive signal RF_{n,input} with the LO signal LO_{I} to generate the common IF band signal S_{IF}_{_{n,I}}, and the mixer 164^{n,Q} mixes the RF receive signal RF_{n,input} with the phase-shifted LO signal LO_{Q} to generate the common IF band signal S_{IF}_{_{n,Q}}.

Each of the bandpass filters 166^{1,I}-166^{n,Q} has an input terminal connected to an output terminal of a corresponding one of the mixers 162^{1,I}-164^{n,Q} and bandpass-filters an output of the corresponding one of the mixers 162^{1,I}-164^{n,Q} to remove unnecessary signal components.

The second frequency converter 180 may include (2n−1) mixers 182^{1,Q}-182^{n,Q} and 2n bandpass filters 184^{1,I}-184^{n,Q}. The mixer 182^{1,Q} mixes the common IF band signal S_{IF}_{_{1,Q}} with an offset oscillation signal having a frequency of Δf to generate the IF signal S_{BB}_{_{1,Q}}. The mixer 182^{2,I} mixes the common IF band signal S_{IF}_{_{2,I}} with an offset oscillation signal having a frequency of 2Δf to generate the IF signal S_{BB}_{_{2,I}}, and the mixer 182^{2,Q} mixes the common IF band signal S_{IF}_{_{2,Q}} with an offset oscillation signal having a frequency of 3Δf to generate the IF signal S_{BB}_{_{2,Q}}. In this way, the mixer 182^{n,I} mixes the common IF band signal S_{IF}_{_{n,I}} with an offset oscillation signal having a frequency of (2n−2)Δf to generate the IF signal S_{BB}_{_{n,I}}, and the mixer 182^{n,Q} mixes the common IF band signal S_{IF}_{_{n,Q}} with an offset oscillation signal having a frequency of (2n−1)Δf to generate the IF signal S_{BB}_{_{n,Q}}. Each of the bandpass filters 184^{1,I}-184^{n,Q} bandpass-filters the IF signals S_{BB}_{_{1,I}}-S_{BB}_{_{n,Q}} to remove unnecessary signal components. Here, the first bandpass filter 184^{1,I} which filters the IF signal S_{BB}_{_{1,I}} for which no mixing operation may be performed may be omitted.

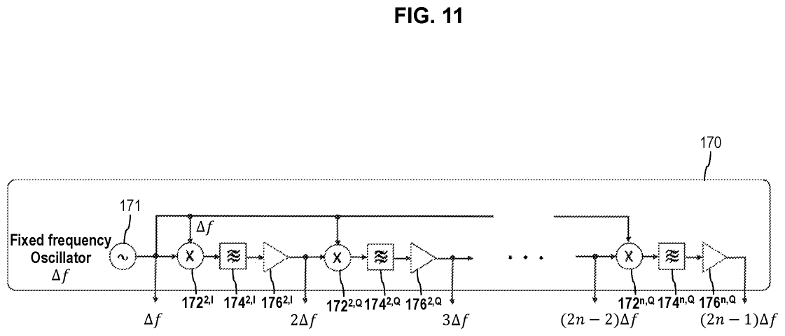

FIG. 11 is a detailed block diagram of a multiple-frequency LO signal generator 170 shown in FIGS. 9 and 10. In the present embodiment, the multiple-frequency LO signal generator 170 may include an oscillator 171, (2n−2) mixers 172^{2,I}-172^{n,Q}, (2n−2) bandpass filters 174^{2,I}-174^{n,Q}, and (2n−2) amplifiers 176^{2,I}-176^{n,Q}.

The oscillator 171 generates the offset oscillation signal having the offset frequency Δf. The mixer 172^{1,Q} may mix the offset oscillation signal with a branched offset oscillation signal to generate the offset oscillation signal having the frequency of 2Δf. The bandpass filter 174^{1,Q} may bandpass-filter the output signal of the mixer 172^{1,Q} to remove unnecessary signal components. The amplifier 176^{1,Q} may amplify the output signal of the bandpass filter 174^{1,Q} to compensate for any signal attenuation in the mixer 172^{1,Q} and/or the bandpass filter 174^{1,Q}.

The mixer 172^{2,I} may mix the offset oscillation signal output by the amplifier 176^{1,Q} and having the frequency of 2Δf with the offset oscillation signal to generate the offset oscillation signal having the frequency of 3Δf. The bandpass filter 174^{2,I} may bandpass-filter the output signal of the mixer 172^{2,I}, and the amplifier 176^{2,I} may amplify the output signal of the bandpass filter 174^{2,I}. The mixer 172^{2,Q} may mix the offset oscillation signal output by the amplifier 176^{2,I} and having the frequency of 3Δf with the offset oscillation signal to generate the offset oscillation signal having the frequency of 4Δf. The bandpass filter 174^{2,Q} may bandpass-filter the output signal of the mixer 172^{2,Q}, and the amplifier 176^{2,Q} may amplify the output signal of the bandpass filter 174^{2,Q}.

Therefore, a circuit of each stage including a combination of a mixer, a bandpass filter, and an amplifier connected in series may generate the offset oscillation signal whose frequency is additionally increased by the offset frequency Δf compared with the output of the circuit of a previous stage.

The frequency downconversion process according to the present embodiment will now be described in more detail.

The I-channel common IF band signal S_{IF}_{_{I}}(t) output by the first frequency converter 160 for the RF receive signal of the m-th path may be expressed by Equation 10.

$${S}_{{IF}_{I}} = \frac{1}{2} {A}_{k} \cdot cos ( 2 π \frac{BW}{{T}_{c}} {τ}_{k} t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) ) \qquad [ Equation 10 ]$$

The offset oscillation signal LO_{m.I}(t) for use in the mixing of the I-channel of the m-th path may be expressed by Equation 11. A band-converted I-channel IF signal S_{BB}_{_{I}}(t) may be expressed by Equation 12.

$${LO}_{m , I} ( t ) = cos ( 2 π ( m Δ f ) t ) \qquad [ Equation 11 ]$$

$$\begin{matrix}{S}_{{BB}_{I}} ( t ) = {S}_{{IF}_{i}} ( t ) \cdot {LO}_{m , I} ( t ) \\ = \frac{1}{2} {A}_{k} \cdot cos ( 2 π \frac{BW}{{T}_{c}} {τ}_{k} t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) ) \cdot cos ( 2 π ( m Δ f ) t ) \\ = \frac{1}{4} {A}_{k} \cdot \{ \begin{matrix}cos ( 2 π \frac{BW}{{T}_{c}} {τ}_{k} t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) - 2 π ( m Δ f ) t ) + \\ cos ( 2 π \frac{BW}{{T}_{c}} {τ}_{k} t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) + 2 π ( m Δ f ) t )\end{matrix} \} \\ = \frac{1}{4} {A}_{k} \cdot \{ \begin{matrix}cos ( 2 π ( m Δ f - \frac{BW}{{T}_{c}} {τ}_{k} ) t - 2 π {f}_{0} {τ}_{k} + 2 π \frac{1}{2} \frac{BW}{{T}_{c}} {τ}_{k}^{2} - {∅}_{0} ( t ) + {∅}_{0} ( t - {τ}_{k} ) ) + \\ cos ( 2 π ( m Δ f + \frac{BW}{{T}_{c}} {τ}_{k} ) t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) )\end{matrix} \}\end{matrix} \qquad [ Equation 12 ]$$

The final IF signal S_{BB}_{_{m,I}} output by the second frequency converter 180 after

$$m Δ f - \frac{BW}{{T}_{c}} {τ}_{k}$$

frequency components are removed and only

$$m Δ f + \frac{BW}{{T}_{c}} {τ}_{k}$$

frequency components are extracted by the bandpass filter 184^{m,I} may be expressed by Equation 13.

$${s}_{{BB}_{I}} ( t ) = \frac{1}{4} {A}_{k} \cdot cos ( 2 π ( m Δ f + \frac{BW}{{T}_{c}} {τ}_{k} ) t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) ) \qquad [ Equation 13 ]$$

As can be seen in the above equation, if the frequency band of each RF receive signal is first converted to the common IF band by using the LO signal having the frequency of f₁ and then the frequency band is upconverted by using the offset oscillation signal having the frequency of mΔf, the frequency band of the IF signal moves by mΔf on the frequency axis. Thus, if the frequency of the LO signal used for the frequency conversion for each path is different from the frequency for the previous path by Δf, the position of the frequency band occupied by each IF signal is changed so that the signals can be combined on the frequency axis without changing other parameters.

The Q-channel IF signal S_{BB}(t) for the Q-channel of the m-th path may also be calculated as follows similarly to the I-channel of the m-th path.

The Q-channel common IF band signal S_{IF}_{_{Q}}(t) output by the first frequency converter 160 for the RF receive signal of the m-th path may be expressed by Equation 14.

$${S}_{{IF}_{Q}} ( t ) = \frac{1}{2} {A}_{k} \cdot sin ( 2 π \frac{BW}{{T}_{c}} {τ}_{k} t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) ) \qquad [ Equation 14 ]$$

The offset oscillation signal LO_{m,Q}(t) for use in the mixing of the Q-channel of the m-th path may be expressed by Equation 15. A band-converted Q-channel IF signal S_{BB}_{_{Q}}(t) may be expressed by Equation 16.

$${LO}_{m , Q} ( t ) = cos ( 2 π ( m Δ f ) t ) \qquad [ Equation 15 ]$$

$$\begin{matrix}{S}_{{BB}_{Q}} ( t ) = {S}_{{IF}_{Q}} ( t ) \cdot {LO}_{m , Q} ( t ) \\ = \frac{1}{2} {A}_{k} \cdot sin ( 2 π \frac{BW}{{T}_{c}} {τ}_{k} t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) ) \cdot cos ( 2 π ( m Δ f ) t ) \\ = \frac{1}{4} {A}_{k} \cdot \{ \begin{matrix}sin ( 2 π \frac{BW}{{T}_{c}} {τ}_{k} t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) + 2 π ( m Δ f ) t ) + \\ sin ( 2 π \frac{BW}{{T}_{c}} {τ}_{k} t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) - 2 π ( m Δ f ) t )\end{matrix} \} \\ = \frac{1}{4} {A}_{k} \cdot \{ \begin{matrix}sin ( 2 π ( m Δ f + \frac{BW}{{T}_{c}} {τ}_{k} ) t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) ) + \\ sin ( 2 π ( m Δ f - \frac{BW}{{T}_{c}} {τ}_{k} ) t - 2 π {f}_{0} {τ}_{k} + 2 π \frac{1}{2} \frac{BW}{{T}_{c}} {τ}_{k}^{2} - {∅}_{0} ( t ) + {∅}_{0} ( t - {τ}_{k} ) )\end{matrix} \}\end{matrix} \qquad [ Equation 16 ]$$

The final IF signal S_{BB}_{_{m,Q}} output by the second frequency converter 180 after

$$m Δ f - \frac{BW}{{T}_{c}} {τ}_{k}$$

frequency components are removed and only the

$$m Δ f + \frac{BW}{{T}_{c}} {τ}_{k}$$

frequency components are extracted by the bandpass filter 184m,Q may be expressed by Equation 17.

$${s}_{{BB}_{Q}} ( t ) = \frac{1}{4} {A}_{k} \cdot sin ( 2 π ( m Δ f + \frac{BW}{{T}_{c}} {τ}_{k} ) t + 2 π {f}_{0} {τ}_{k} - 2 π \frac{1}{2} \frac{BW}{{T}_{c}} {τ}_{k}^{2} + {∅}_{0} ( t ) - {∅}_{0} ( t - {τ}_{k} ) ) \qquad [ Equation 17 ]$$

For the Q-channel also, if the frequency band of each RF receive signal is first converted to the common IF band by using the LO signal having the frequency of f₁ and then the frequency band is upconverted by using the offset oscillation signal having the frequency of mΔf, the frequency band of the IF signal moves by mΔf on the frequency axis. Thus, if the frequency of the LO signal used for the frequency conversion for each path is different from the frequency for the previous path by Δf, the position of the frequency band occupied by each IF signal is changed so that the signals can be combined on the frequency axis without changing other parameters.

The operation of the digital signal processor according to exemplary embodiments of the present disclosure can be implemented by computer-readable program codes or instructions stored on a computer-readable intangible recording medium. The computer-readable recording medium includes all types of recording device storing data which can be read by a computer system. The computer-readable recording medium may be distributed over computer systems connected through a network so that the computer-readable program or codes may be stored and executed in a distributed manner.

The computer-readable recording medium may include a hardware device specially configured to store and execute program instructions, such as a ROM, RAM, and flash memory. The program instructions may include not only machine language codes generated by a compiler, but also high-level language codes executable by a computer using an interpreter or the like.

Some aspects of the present disclosure described above in the context of the device may indicate corresponding descriptions of the method according to the present disclosure, and the blocks or devices may correspond to operations of the method or features of the operations. Similarly, some aspects described in the context of the method may be expressed by features of blocks, items, or devices corresponding thereto. Some or all of the operations of the method may be performed by use of a hardware device such as a microprocessor, a programmable computer, or electronic circuits, for example. In some exemplary embodiments, one or more of the most important operations of the method may be performed by such a device.

In some exemplary embodiments, a programmable logic device such as a field-programmable gate array may be used to perform some or all of functions of the methods described herein. In some exemplary embodiments, the field-programmable gate array may be operated with a microprocessor to perform one of the methods described herein. In general, the methods are preferably performed by a certain hardware device.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

What is claimed is:

1. A radar apparatus, comprising:
a transmit circuit configured to generate a RF transmit signal based on a local oscillation signal and comprising a transmit antenna radiating a transmit electromagnetic signal corresponding to the RF transmit signal;
a receive circuit configured to detect, through a plurality of antennas, receive electromagnetic signals that the transmit electromagnetic signal was reflected by a target and propagated toward the radar apparatus and amplify detected signals to acquire n-tuple RF receive signals (where n is a natural number greater than or equal to 2);
a frequency downconverter configured to convert each of the RF receive signals into an in-phase (I)-channel IF signal and a quadrature (Q)-channel IF signal such that frequency bands of 2n IF signals for the RF receive signals are sequentially displaced by a predetermined offset frequency;
an analog-to-digital converter configured to perform an analog-to-digital conversion of a single IF signal into which the 2n IF signals are combined to generate a single digital signal stream; and
a digital signal processor configured to processes the digital signal stream to extract target information.

2. The radar apparatus of claim 1, wherein the frequency downconverter is configured to convert a frequency band of each RF receive signal into a first IF band to generate the I-channel IF signal, and shift a phase of the RF receive signal by 90 degrees and convert a frequency band of a phase-shifted RF receive signal into a second IF band different from the first IF band to generate the Q-channel IF signal.

3. The radar apparatus of claim 2, wherein the frequency downconverter is configured to convert the RF receive signals into the 2n IF signals such that 2n IF bands of the 2n IF signals are sequentially displaced in a frequency domain by a predetermined offset frequency.

4. The radar apparatus of claim 3, wherein the offset frequency is set to be equal to a signal bandwidth of a beat frequency of the radar apparatus.

5. The radar apparatus of claim 3, wherein the offset frequency is set to be greater than a signal bandwidth of a beat frequency of the radar apparatus.

6. The radar apparatus of claim 3, wherein the receive circuit comprises:
the plurality of antennas each configured to detect one of the electromagnetic signals and convert a detected electromagnetic signal into an electrical signal to output one of the RF receive signals; and
a plurality of low noise amplifiers each configured to amplify a corresponding one of the RF receive signals.

7. The radar apparatus of claim 6, wherein the frequency downconverter comprises:
a multiple-frequency local oscillation signal generator configured to generate (2n−1) adjusted oscillation signals having frequencies sequentially added with the offset frequency from a base frequency of the local oscillation signal and output 2n oscillation signals including the local oscillation signal and the adjusted oscillation signals, wherein the 2n oscillation signals comprises n-tuple oscillation signal pairs of two oscillation signals being out of phase by 90 degrees from each other; and
a frequency conversion circuit configured to mix each of the RF receive signals with two oscillation signals of a corresponding oscillation signal pair among the 2n oscillation signals to generate the 2n IF signals.

8. The radar apparatus of claim 6, wherein the frequency downconverter comprises:
a first frequency converter configured to mix each of the RF receive signals with the local oscillation signal and a phase-shifted local oscillation signal whose phase is shifted by 90 degrees from the local oscillation signal to generate 2n common IF band signals;
a multiple-frequency local oscillation signal generator configured to generate (2n−1) offset oscillation signals having frequencies sequentially added with the offset frequency from the offset frequency; and
a second frequency converter configured to mix each of a second and subsequent common IF band signals among the 2n common IF band signals with the (2n−1) offset oscillation signals, respectively, to generate the 2n IF signals including a first common IF band signal.

9. A signal processing method in a radar apparatus, comprising:
detecting, by a plurality of antennas, electromagnetic signals that a transmit electromagnetic signal was reflected by a target and propagated toward the radar apparatus and amplifying detected signals to acquire n-tuple RF receive signals (where n is a natural number greater than or equal to 2);
converting each of the RF receive signals into an in-phase (I)-channel IF signal and a quadrature (Q)-channel IF signal such that frequency bands of 2n IF signals for the RF receive signals are different from each other;
combining the 2n IF signals to obtain a single IF signal and performing an analog-to-digital conversion of the single IF signal to generate a single digital signal stream; and
processing the digital signal stream to extract target information.

10. The signal processing method of claim 9, wherein converting each of the RF receive signals into the I-channel IF signal and the Q-channel IF signal comprises:
converting a frequency band of each RF receive signal into a first IF band to generate the I-channel IF signal; and
shifting a phase of the RF receive signal by 90 degrees and converting a frequency band of a phase-shifted RF receive signal into a second IF band different from the first IF band to generate the Q-channel IF signal.

11. The signal processing method of claim 9, wherein the RF receive signals are converted into the 2n IF signals such that 2n IF bands of the 2n IF signals are sequentially displaced in a frequency domain by a predetermined offset frequency.

12. The signal processing method of claim 11, wherein the offset frequency is set to be equal to a signal bandwidth of a beat frequency of the radar apparatus.

13. The signal processing method of claim 11, wherein the offset frequency is set to be greater than a signal bandwidth of a beat frequency of the radar apparatus.

14. The signal processing method of claim 11, wherein converting each of the RF receive signals into the I-channel IF signal and the Q-channel IF signal comprises:
generating 2n oscillation signals including the local oscillation signal used for generating the transmit electromagnetic signal and (2n−1) adjusted oscillation signals having frequencies sequentially added with the offset frequency from a base frequency of the local oscillation signal, wherein the 2n oscillation signals comprises n-tuple oscillation signal pairs of two oscillation signals being out of phase by 90 degrees from each other; and
mixing each of the RF receive signals with two oscillation signals of a corresponding oscillation signal pair among the 2n oscillation signals to generate the 2n IF signals.

15. The signal processing method of claim 11, wherein converting each of the RF receive signals into the I-channel IF signal and the Q-channel IF signal comprises:
mixing each of the RF receive signals with the local oscillation signal used for generating the transmit electromagnetic signal and a phase-shifted local oscillation signal whose phase is shifted by 90 degrees from the local oscillation signal to generate 2n common IF band signals;
converting the 2n common IF band signals into the 2n IF signals in respective IF bands sequentially displaced by the offset frequency.

16. The signal processing method of claim 15, wherein converting the 2n common IF band signals into the 2n IF signals comprises:
generating (2n−1) offset oscillation signals having frequencies sequentially added with the offset frequency from the offset frequency; and
mixing each of a second and subsequent common IF band signals among the 2n common IF band signals with the (2n−1) offset oscillation signals, respectively, to generate the 2n IF signals including a first common IF band signal.
